(19) United States
(12) Patent Application Publication
(10) Pub. No.: US 2019/0368024 A1
(43) Pub. Date: Dec. 5, 2019

(54) POSITIONING ARRANGEMENT FOR A SUBSTRATE CARRIER AND A MASK CARRIER, TRANSPORTATION SYSTEM FOR A SUBSTRATE CARRIER AND A MASK CARRIER, AND METHODS THEREFOR

(71) Applicant: Applied Materials, Inc., Santa Clara, CA (US)

(72) Inventors: Matthias HEYMANNS, Münster (DE); Oliver HEIMEL, Wabern (DE); Stefan BANGERT, Steinau (DE); Jürgen HENRICH, Limeshain (DE); Andreas SAUER, Großostheim (DE); Tommaso VERCESI, Aschaffenburg (DE)

(21) Appl. No.: 15/748,885

(22) PCT Filed: Feb. 24, 2017
(86) PCT No.: PCT/EP2017/054356

§ 371 Date: Jan. 30, 2018

(51) Int. Cl. C23C 14/04; C23C 14/50; H01L 21/677; H01L 21/68

(52) U.S. Cl. CPC C23C 14/042; C23C 14/50; H01L 21/682; H01L 21/67712; H01L 21/67709

(57) ABSTRACT

A positioning arrangement for positioning a substrate carrier and a mask carrier in a vacuum chamber is described. The positioning arrangement comprising a first track extending in a first direction and configured transportation of the substrate carrier configured for holding a substrate having a substrate surface, a second track extending in the first direction and configured for transportation of the mask carrier, wherein the first track and the second track are offset by an offset distance in a plane coplanar with the substrate surface, and a holding arrangement configured for holding the mask carrier, wherein the holding arrangement is arranged between the first track and the second track.

### TECHNICAL FIELD

Embodiments of the present disclosure relate to apparatuses and methods for positioning and transportation of carriers. In particular, embodiments of the present disclosure relate to apparatuses and methods for positioning and transportation of substrate carriers and mask carriers in a processing system having a vacuum process chamber, particularly for OLED manufacturing.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness and viewing angles possible with OLED displays is greater than that of traditional LCD displays because OLED pixels directly emit light and do not involve a back light. Therefore, the energy consumption of OLED displays is considerably less than that of traditional LCD displays. Further, the fact that OLEDs can be manufactured onto flexible substrates results in further applications.

The functionality of an OLED depends on the coating thickness of the organic material. This thickness has to be within a predetermined range. In the production of OLEDs, there are technical challenges with respect to the deposition of evaporated materials in order to achieve high resolution OLED devices. In particular, accurate and smooth transportation of substrate carriers and mask carriers through a processing system remains challenging. Further, a precise alignment of the substrate with respect to the mask is crucial for achieving high quality processing results, e.g. for production of high resolution OLED devices.

Accordingly, there is a continuing demand for providing improved apparatuses and methods for positioning and transportation of substrate carriers and mask carriers.

### SUMMARY

In light of the above, a positioning arrangement, a transportation system, a vacuum processing system, method for positioning a substrate carrier relative to a mask carrier, and a method for transporting a substrate carrier and a mask carrier through a processing system according to the independent claims are provided. Further aspects, benefits, and features of the present disclosure are apparent from the claims, the description, and the accompanying drawings.

According to an aspect of the present disclosure, a positioning arrangement for positioning a substrate carrier and a mask carrier in a vacuum chamber is provided. The positioning arrangement includes a first track extending in a first direction and configured for transportation of the substrate carrier configured for holding a substrate having a substrate surface. Further, the positioning arrangement includes a second track extending in the first direction and configured for transportation of the mask carrier. The first track and the second track are offset by an offset distance in a plane coplanar with the substrate surface. Further, the the positioning arrangement includes a holding arrangement configured for holding the mask carrier, wherein the holding arrangement is arranged between the first track and the second track.

According to another aspect of the present disclosure, a transportation system for transporting a substrate carrier and a mask carrier in a processing system is provided. The transportation system includes a first track extending in a first direction and configured for contactless transportation of the substrate carrier configured for holding a substrate having a substrate surface. Further, the transportation system includes a second track extending in the first direction and configured for contactless transportation of the mask carrier. The first track and the second track are offset by an offset distance in a plane coplanar with the substrate surface.

According to a further aspect of the present disclosure, a vacuum processing system is provided. The vacuum processing system includes a vacuum processing chamber having a positioning arrangement according to any embodiments described herein. Further, the vacuum processing system includes at least one further chamber having a transportation system according to any embodiments described herein.

According to another aspect of the present disclosure, a method for positioning a substrate carrier relative to a mask carrier is provided. The method includes positioning the substrate carrier in a first position by using a first track configured for contactless transportation of the substrate carrier; positioning the mask carrier in a second position by using a second track configured for contactless transportation of the mask carrier; holding the mask carrier by using a holding arrangement arranged between the first track and the second track; and aligning the substrate carrier relative to the mask carrier.

According to yet another aspect of the present disclosure, a method for transporting a substrate carrier and a mask carrier through a processing system is provided. The method includes transporting the substrate carrier on a first track configured for contactless transportation of the substrate carrier configured for holding a substrate having a substrate surface; and transporting the mask carrier on a second track configured for contactless transportation of the mask carrier, wherein the first track and the second track are offset by an offset distance in a plane coplanar with the substrate surface.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic front view of a positioning arrangement for positioning a substrate carrier and a mask carrier according to embodiments described herein;

FIG. 1B shows a schematic side view of a positioning arrangement according to further embodiments described herein;

FIG. 2A shows a schematic front view of a positioning arrangement according to further embodiments described herein;

FIG. 2B shows a schematic side view of a positioning arrangement according to further embodiments described herein;

FIG. 3 shows a schematic perspective view of a mask carrier holding arrangement of a positioning arrangement according to embodiments described herein;

FIG. 4 shows a schematic side view of a positioning arrangement having a mask carrier holding arrangement according to embodiments described herein;

FIGS. 5A and 5B show schematic front views of a portion of a positioning arrangement according to further embodiments described herein;

FIG. 6 shows a schematic side view of a positioning arrangement according to further embodiments described herein;

FIG. 7A shows a schematic front view of a transportation system for transporting a substrate carrier and a mask carrier in a processing system according to embodiments described herein;

FIG. 7B shows a schematic side view of a transportation system according to embodiments described herein as shown in FIG. 7A;

FIG. 8 shows a schematic view of vacuum processing system according to embodiments described herein,

FIG. 9 shows a flow chart illustrating a method for positioning a substrate carrier relative to a mask carrier according to embodiments described herein, and

FIG. 10 shows a flow chart illustrating a method for transporting a substrate carrier and a mask carrier through a processing system according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment can apply to a corresponding part or aspect in another embodiment as well.

Before various embodiments of the present disclosure are described in more detail, some aspects with respect to some terms and expressions used herein are explained.

In the present disclosure, a “positioning arrangement” is to be understood as an arrangement which is configured for positioning of a carrier, particularly a substrate carrier and/or a mask carrier. In particular, a positioning arrangement as described herein can be understood as an arrangement which is configured for moving a substrate carrier and/or a mask carrier along a transportation track. More specifically, the positioning arrangement can be configured for positioning the substrate carrier in a first position by moving the substrate carrier along a first track. Additionally, the positioning arrangement can be configured for positioning the mask carrier in a second position by moving the mask carrier along a second track. For instance, the first track and the second track can be configured for contactless transportation. Accordingly, it is to be understood that the positioning arrangement as described herein is configured for moving the substrate carrier and the mask carrier independently from each other, such that the substrate carrier and the mask carrier can be positioned relatively to each other, e.g. for aligning the substrate carrier with the mask carrier.

In the present disclosure, a “substrate carrier” is to be understood as a carrier which is configured for holding a substrate as described herein, particularly a large area substrate. Typically, the substrate held or supported by the substrate carrier includes a front surface and a back surface, wherein the front surface is a surface of the substrate being processed, for example on which a material layer is to be deposited.

The term “substrate” as used herein may particularly embrace substantially inflexible substrates, e.g., glass plates and metal plates. However, the present disclosure is not limited thereto and the term “substrate” can also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.5 mm or below, wherein the flexibility of the substantially inflexible substrate is small in comparison to the flexible substrates. According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

According to some embodiments, the substrate can be a “large area substrate” and may be used for display manufacturing. For instance, a “large area substrate” can have a main surface with an area of 0.5 m² or larger, particularly of 1 m² or larger. In some embodiments, a large area substrate can be GEN 4.5, which corresponds to about 0.67 m² of substrate (0.73×0.92m), GEN 5, which corresponds to about 1.4 m² of substrate (1.1 m×1.3 m), GEN 7.5, which corresponds to about 4.29 m² of substrate (1.95 m×2.2 m), GEN 8.5, which corresponds to about 5.7 m² of substrate (2.2 m×2.5 m), or even GEN 10, which corresponds to about 8.7 m² of substrate (2.85 m×3.05 m). Even larger generations such as GEN 11 and GEN 12 and corresponding substrate areas can similarly be implemented.

In the present disclosure, a “mask carrier” is to be understood as a carrier which is configured for holding a mask. For instance, the mask may be an edge exclusion mask or a shadow mask. An edge exclusion mask is a mask which is configured for masking one or more edge regions of the substrate, such that no material is deposited on the one or more edge regions during the coating of the substrate. A shadow mask is a mask configured for masking a plurality of features which are to be deposited on the substrate. For instance, the shadow mask can include a plurality of small openings, e.g. a grid of small openings.

In the present disclosure, a “track configured for contactless transportation” is to be understood as a track which is configured for contactless transportation of a carrier, particularly a substrate carrier or a mask carrier. The term “contactless” can be understood in the sense that the weight of the carrier, e.g. of the substrate carrier or mask carrier, is not held by a mechanical contact or mechanical forces, but is held by a magnetic force. In particular, the carrier can be held in a levitating or floating state using magnetic forces instead of mechanical forces. For example, in some implementations, there can be no mechanical contact between the carrier and the transportation track, particularly during levitation, movement and positioning of the substrate carrier and/or mask carrier.

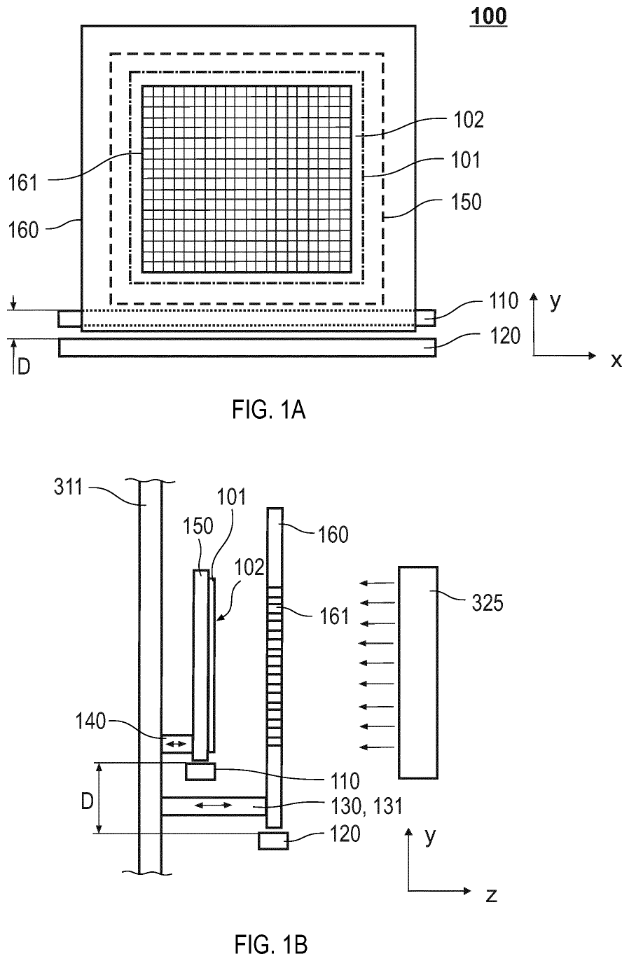

In the present disclosure, the expression “offset by an offset distance in a plane coplanar with the substrate surface” is to be understood as a configuration in which an offset distance is provided in a direction of the substrate surface extension. Accordingly, the expression that the “first track and the second track are offset by an offset distance in a plane coplanar with the substrate surface” can be understood in that a distance between the first track and the second track is provided, wherein the distance is coplanar with the substrate surface. However, it is to be understood that the first track and the second track do not have to be arranged in plane coplanar with the substrate surface. In particular, e.g. from FIG. 1B, it is to be understood that the first track and/or the second track can be arranged in respective different planes not being coplanar with the substrate surface. For instance, the first track and the second track may be spaced apart in a lateral direction, e.g. the z-direction as exemplarily shown in FIG. 1B. In particular, the first track and the second track may be offset by a vertical offset distance, e.g. in a direction of the gravitational force.

FIG. 1A shows a schematic front view of a positioning arrangement 100 according to embodiments described herein. In particular, according to embodiments which can be combined with any other embodiment described herein, the positioning arrangement 100 is configured for positioning a substrate carrier 150 and a mask carrier 160 in a vacuum chamber, for instance in a vacuum processing chamber of a processing system as described herein. Typically, the positioning arrangement 100 includes a first track 110 extending in a first direction. For example, in FIG. 1A the first direction corresponds to the x-direction. Further, according to embodiments described herein, the first track 110 can be configured for contactless transportation of the substrate carrier 150. Typically, the substrate carrier 150 is configured for holding a substrate 101 having a substrate surface 102. Further, the positioning arrangement 100 includes a second track 120 extending in the first direction, e.g. the x-direction as shown in FIG. 1A. For example, the second track 120 can be configured for contactless transportation of the mask carrier 160. As exemplarily shown in FIG. 1A, the first track 110 and the second track 120 are offset by an offset distance D in a plane coplanar with the substrate surface. In particular, as exemplarily shown in FIG. 1B, the first track 110 and the second track 120 may be arranged between a wall of vacuum processing chamber 311 and a deposition source 325.

Accordingly, beneficially an improved apparatus for positioning a substrate carrier and a mask carrier is provided. In particular, by providing a positioning arrangement which is configured for contactless transportation of a substrate carrier and the mask carrier, beneficially a generation of particles, e.g. generated due to a mechanical contact between the carriers and the transportation tracks, can be avoided during transportation and alignment of the carriers. Accordingly, embodiments described herein provide for an improved purity and uniformity of the layers deposited on the substrate, in particular since a particle generation is minimized when using the contactless levitation, transportation and/or alignment. Further, by providing a positioning arrangement wherein a first track for a substrate carrier is offset by an offset distance with respect to a second track for a mask carrier, structural advantages for providing further structural elements, e.g. a holding arrangement for a mask carrier, can be provided.

According to embodiments which can be combined with any other embodiments described herein, the offset distance D may be between a lower limit of D≥100 mm, particularly a lower limit of D≥150 mm, more particularly a lower limit of D≥200 mm and an upper limit of D≤250 mm cm, particularly an upper limit of D≤300 mm, more particularly an upper limit of D≤400 mm. For instance, the offset distance D can be 180 mm≤D≤220 mm. According to an example, the offset distance D may be 201 mm.

As exemplarily shown in FIGS. 1A and 1B, the offset distance D can be defined as a distance between a surface of the first track which faces the substrate carrier and a surface of the second track which faces the mask carrier. For instance, the surface of the first track facing the substrate carrier can be a top surface of the first track and the surface of the second track facing the mask carrier can be a top surface of the second track. In particular, from FIGS. 1A and 1B, it is to be understood that the top surface of the first track may lie in an x-z-plane and the top surface of the second track may lie in a parallel x-z-plane.

With exemplary reference to FIG. 1B, according to embodiments which can be combined with any other embodiments described herein, the positioning arrangement 100 may further include a holding arrangement 130 configured for holding the mask carrier 160. In particular, the holding arrangement can be arranged between the first track 110 and the second track 120. In particular, the holding arrangement 130 can be arranged in a region of the offset distance D, as exemplarily shown in FIG. 1B. Typically, the holding arrangement is configured for holding the mask carrier in a predetermined position. Further, optionally, the holding arrangement can be configured for positioning the mask carrier relative to the substrate carrier. Accordingly, by providing a holding arrangement between the first track and the second track of the positioning arrangement, an improved apparatus for positioning a substrate carrier and a mask carrier can be provided.

With exemplary reference to FIG. 1B, according to embodiments which can be combined with any other embodiments described herein, the holding arrangement 130 may include at least one holding element 131 configured to be movable in a moving direction being different to a substrate transport direction, as exemplarily shown in FIG. 1B. For instance, the at least one holding element 131 can be configured to be movable in a direction substantially perpendicular to a plane of the substrate surface, e.g. in a z-direction as exemplarily shown in FIG. 1B. In FIG. 1B, a moving direction of the at least one holding element 131 is indicated by the double sided arrow depicted on the holding element. According to some embodiments which can be combined with other embodiments described herein, the holding arrangement 130, particularly the at least one holding element 131, may be configured to be movable in an x-direction and/or a y-direction and/ or and a z-direction. As an example, the at least one holding element may include at least one actuator selected from the group consisting of: a stepper actuator, a brushless actuator, a DC (direct current) actuator, a voice coil actuator, a piezoelectric actuator, and any combination thereof. Accordingly, beneficially the mask carrier can be transported on the second track to a predetermined position at which the holding arrangement, particularly the movable holding element, can move towards the mask carrier in order to hold the mask carrier in the predetermined position.

According to some embodiments which can be combined with other embodiments described herein, at least one holding element can be configured to be connected to a mask carrier with magnetic forces. For example, the at least one holding element may include an electromagnet, which can be switched on for engaging the holding element to a mask carrier.

Further, with exemplary reference to FIG. 1B, according to embodiments which can be combined with any other embodiments described herein, the positioning arrangement 100 can include an alignment system 140 configured for aligning the substrate carrier relative to the mask carrier. In particular, the alignment system 140 can be configured to adjust the position of the substrate carrier with respect to the mask carrier. For example, the alignment system 140 can include two or more alignment actuators, for example four alignment actuators. For instance, typically the alignment system 140 is configured for aligning the substrate carrier holding a substrate relative to the mask carrier holding a mask in order to provide for a proper alignment between the substrate and the mask during material deposition, e.g. of the organic material. In particular, the alignment system 140 can be configured to align the substrate carrier in an x-direction and/or a y-direction and/or and a z-direction. Accordingly, an alignment system as described herein allows for an improved alignment of the substrate relative to the mask, which is beneficial for high quality or OLED display manufacturing.

According to some embodiments, the alignment system 140 may include a substrate holding arrangement which may include one or more substrate holding elements. For instance, the one or more substrate holding elements can be configured to be connected to a substrate carrier with magnetic forces. For example, the one or more substrate holding elements may include an electromagnet, which can be switched on for engaging the holding element to a substrate carrier.

In some implementations, the alignment system includes one or more piezoelectric actuators for positioning the substrate carrier and the mask carrier with respect to each other. As an example, the two or more alignment actuators can be piezoelectric actuators for positioning the substrate carrier and the mask carrier with respect to each other. However, the present disclosure is not limited to piezoelectric actuators. As an example, the two or more alignment actuators can be electric or pneumatic actuators. The two or more alignment actuators can for example be linear alignment actuators. In some implementations, the two or more alignment actuators can include at least one actuator selected from the group consisting of: a stepper actuator, a brushless actuator, a DC (direct current) actuator, a voice coil actuator, a piezoelectric actuator, and any combination thereof.

Accordingly, it is to be understood that the mask carrier may be moved into a predetermined mask position on the second track, thereafter a holding arrangement as described herein may move forward to hold the mask carrier. After the mask carrier is positioned, the substrate carrier may be moved into a predetermined substrate position. Then the substrate carrier can be aligned, e.g. by an alignment system as described herein, with respect to the mask carrier.

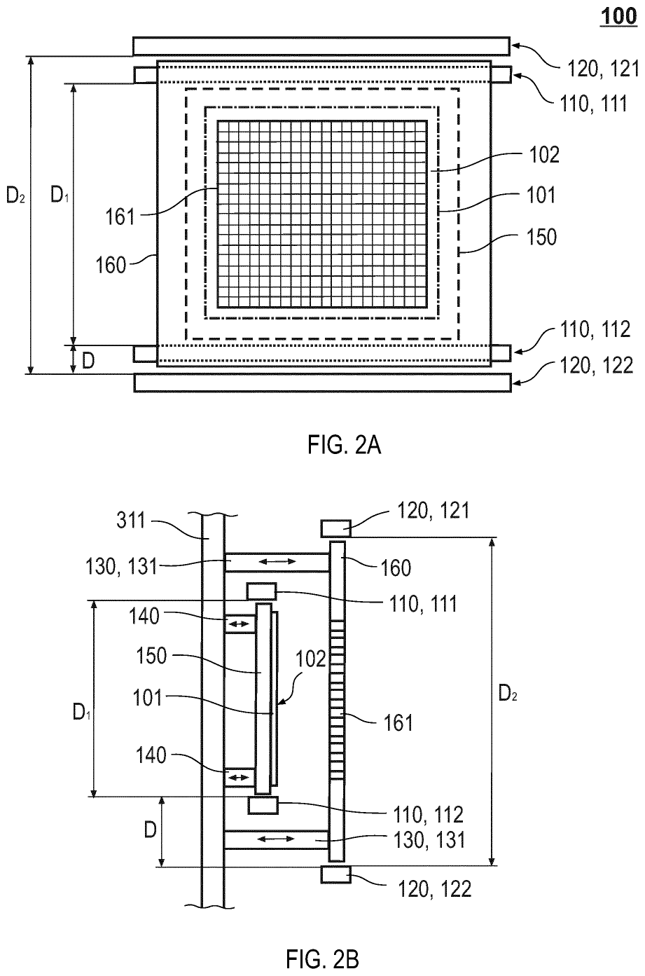

With exemplary reference to FIGS. 2A and 2B, according to embodiments which can be combined with any other embodiments described herein, the first track 110 may include a first guiding structure 111 and a first drive structure 112 which are spaced apart by a first distance D1. Further, the second track can include a second guiding structure 121 and a second drive structure 122 which are spaced apart by a second distance D2. In particular, typically the first distance D1 is smaller than the second distance D2, as exemplarily shown in FIGS. 2A and 2B.

According to embodiments which can be combined with any other embodiments described herein, the first distance D1 may be between a lower limit of D1≥0.7 m, particularly a lower limit of D1≥0.9 m, more particularly a lower limit of D1≥1.1 m and an upper limit of D≤1.5 m, particularly an upper limit of D≤2.0 m, more particularly an upper limit of D≤3.0 m, for instance an upper limit of D≤4.0 m or more.

According to embodiments which can be combined with any other embodiments described herein, the first distance D2 may be between a lower limit of D2≥0.85 m, particularly a lower limit of D2≥1.2 m, more particularly a lower limit of D2≥1.5 m and an upper limit of D2≤2.2 m, particularly an upper limit of D2≤3.3 m, more particularly an upper limit of D2≤4.4 m or more.

Accordingly, as exemplarily shown in FIGS. 2A and 2B, according to embodiments which can be combined with other embodiments described herein, the holding arrangement 130 may be arranged between the first guiding structure 111 and the second guiding structure 121 as well as between the first drive structure 112 and the second drive structure 122. Beneficially, the holding arrangement 130 may include at least one holding element 131 as described herein being arranged between the first guiding structure 111 and the second guiding structure 121. Further, beneficially the holding arrangement 130 may include at least one holding element 131 as described herein being arranged between the first drive structure 112 and the second drive structure 122, as exemplarily shown in FIG. 2B.

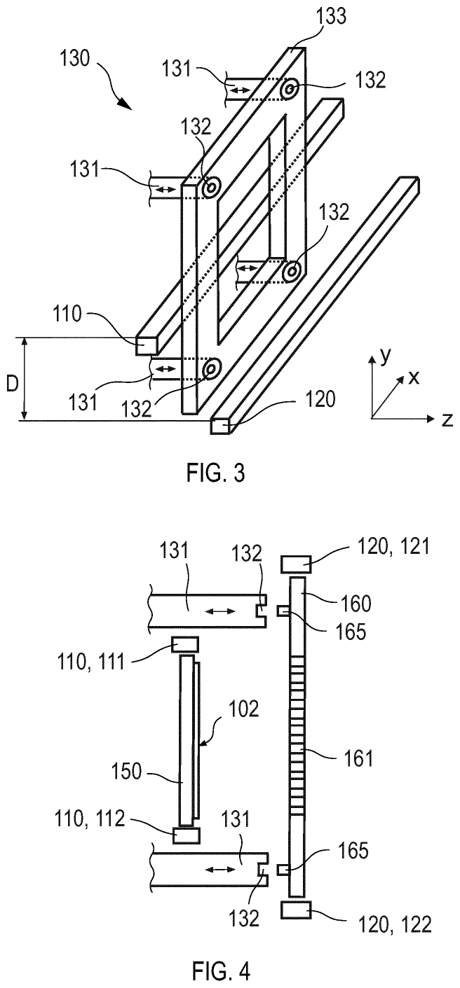

FIG. 3 shows a schematic perspective view of a holding arrangement 130 configured for holding the mask carrier, which may also be referred to as mask carrier holding arrangement herein. As exemplarily shown in FIG. 3, according to embodiments which can be combined with other embodiments described herein, the at least one holding element 131 of the holding arrangement 130 may include at least two holding elements, e.g. three holding elements, four holding elements, or more. For instance, the holding elements may be connected with each other by frame 133, e.g. a frame structure of solid material, which can be beneficial for the structural stability of the holding arrangement. Further, as exemplarily shown in FIG. 3, the at least one holding element 131 can have a reception 132 which can be configured for being connected to at least one mating connecting element provided on the mask carrier, as exemplarily shown in FIG. 4. For instance, the at least one connecting element 165 may be configured as a locking bolt. In particular, the mask carrier may include four connecting elements configured and arranged for being connected to corresponding receptions provided in the frame 133, e.g. one reception 132 on each corner of the frame 133 as exemplarily shown in FIG. 3. Accordingly, when the mask carrier is in the predetermined position, the holding arrangement and the locking bolts can beneficially be employed for holding the correct position of the mask carrier.

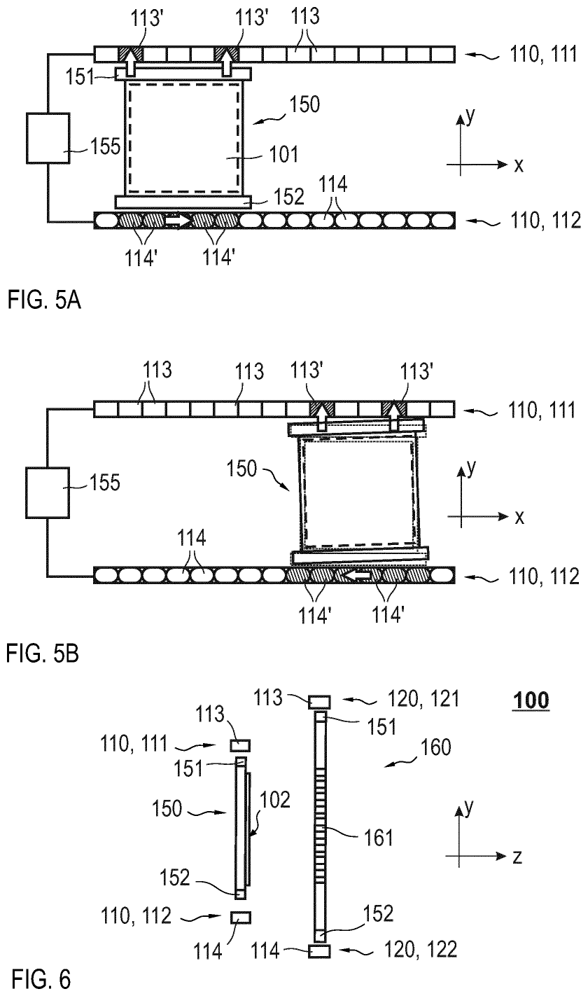

With exemplary reference to FIGS. 5A, 5B and 6, further optional details with respect to the configuration of the first track 110 and the second track 120 of the positioning arrangement according to embodiments described herein are described. In particular, as exemplarily shown in FIGS. 5A and 5B, the first guiding structure 111 of the first track 110 can be a first magnetic guiding structure and the first drive structure 112 of the first track 110 can be a first magnetic drive structure.

It is to be understood that the features as described in connection with the first magnetic guiding structure of the first track 110 as well as in connection with the first magnetic drive structure of the first track 110 can also be applied to the second guiding structure 121 and the second drive structure 122, respectively. Accordingly, with exemplary reference to FIG. 6, the second guiding structure 121 may be configured as a second magnetic guiding structure and the second drive structure 122 may be configured as a second magnetic drive structure, as exemplarily described with reference to FIGS. 5A and 5B.

With exemplary reference to FIGS. 5A and 5B showing schematic front views of a portion of a positioning arrangement, further optional features are described. For the sake of clarity, FIGS. 5A and 5B only illustrate the first track of the positioning arrangement. As exemplarily shown in FIGS. 5A and 5B, the first guiding structure 111 of the first track 110 may extend in a substrate carrier transportation direction, e.g. the x-direction as shown in FIGS. 5A and 5B. The first guiding structure 111 can include a plurality of active magnetic elements 113. Further, as exemplarily shown in FIGS. 5A and 5B, the substrate carrier 150 may include a first passive magnetic element 151. For example, the first passive magnetic element 151 can be a bar or a rod of a ferromagnetic material which can be a portion of the substrate carrier 150. Alternatively, the first passive magnetic element 151 may be integrally formed with substrate carrier 150.

Typically, an active magnetic element of the plurality of active magnetic elements 113 is configured for providing magnetic force interacting with the first passive magnetic element 151 of the substrate carrier 150. In particular, the first passive magnetic element 151 and the plurality of active magnetic elements 113 of the first guiding structure 111 can be configured for providing a magnetic levitation force for levitating the substrate carrier 150, as exemplarily indicated by the vertical arrows pointing towards the first guiding structure 111 in FIGS. 5A and 5B. In other words, the plurality of active magnetic elements 113 are configured for providing a magnetic force on the first passive magnetic element 151 and, thus, on the substrate carrier 150. Accordingly, the plurality of active magnetic elements 113 can levitate the substrate carrier 150, as exemplarily indicated in FIG. 5A.

Further, as exemplarily shown in FIG. 5A, the first track 110 may include a first drive structure 112. In particular, the first drive structure 112 can include a plurality of further active magnetic elements 114. Typically, the further active magnetic elements 114 are configured to drive the substrate carrier along a substrate transport direction, for example along the X-direction shown in FIGS. 5A and 5B. Accordingly, the plurality of further active magnetic elements 114 can form the first drive structure 112 for moving the substrate carrier 150 while being levitated by the plurality of active magnetic elements 113. As exemplarily shown in FIGS. 5A and 5B, the substrate carrier 150 can include a second passive magnetic element 152, e.g. a bar of ferromagnetic material configured to interact with the further active magnetic elements 114 of the first drive structure 112. The second passive magnetic element 152 can be connected to the substrate carrier 150 or be integrally formed with the substrate carrier.

Typically, the further active magnetic elements 114 can be configured to interact with the second passive magnetic element 152 for providing a force along the substrate transport direction. For example, the second passive magnetic element 152 can include a plurality of permanent magnets, which are arranged with an alternating polarity. The resulting magnetic fields of the second passive magnetic element 152 can interact with the plurality of further active magnetic elements 114 to move the substrate carrier 150 while being levitated.

In order to levitate the substrate carrier 150 with the plurality of active magnetic elements 113 and/or to move the substrate carrier 150 with the plurality of further active magnetic elements 114, the active magnetic elements can be controlled to provide adjustable magnetic fields. The adjustable magnetic field may be a static or a dynamic magnetic field. According to embodiments, which can be combined with other embodiments described herein, an active magnetic element as described herein can be configured for generating a magnetic field for providing a magnetic levitation force, for instance extending along a vertical direction, e.g. the y-direction shown in FIGS. 5A and 5B. Additionally or alternatively, an active magnetic element as described herein may be configured for providing a magnetic force extending along a transversal direction. In particular, an active magnetic element as described herein may be or include an element selected from the group consisting of: an electromagnetic device; a solenoid; a coil; a superconducting magnet; or any combination thereof.

As shown in FIGS. 5A and 5B, the first guiding structure 111 may extend along a transport direction of the substrate carrier 150, i.e. the x-direction indicated in FIGS. 5A and 5B. In particular, the first guiding structure 111 may have a linear shape extending along the substrate transport direction. The length of the first track, e.g. the first guiding structure 111 and the first drive structure 112, along the substrate transportation direction may be from 1 to 30 m. Accordingly from FIGS. 5A and 5B showing the substrate carrier 150 at different positions along the first track 110, it is to be understood that during operation of the positioning arrangement 100, the substrate carrier 150 can be moved along the first track 110 in the transportation direction, e.g. along the x-direction. For illustration purposes, the horizontal arrows in FIGS. 5A and 5B indicate a possible driving force of the first drive structure 112 for moving the substrate carrier, e.g. from left to right and vice versa, along the first track 110 shown in FIGS. 5A and 5B.

As exemplarily shown in FIGS. 5A and 5B, two or more active magnetic elements 113′ can be activated by a substrate carrier controller 155 to generate a magnetic field for levitating the substrate carrier 150. For instance, during operation, the substrate carrier 150 may hang below the first guiding structure 111 without mechanical contact. Accordingly, from FIGS. 5A and 5B, it to be understood that the first passive magnetic element 151 may have magnetic properties substantially along the length of the first passive magnetic element 151 in the transport direction. The magnetic field generated by the active magnetic elements 113′ interacts with the magnetic properties of the first passive magnetic element 151 to provide for a first magnetic levitation force and a second magnetic levitation force, as exemplarily indicated by the vertical arrows in FIGS. 5A and 5B. Accordingly, a contactless levitation, transportation and alignment of the substrate carrier 150 can be provided. In FIG. 5A, two active magnetic elements 113′ provide a magnetic force, which is indicated by the vertical arrows. The magnetic forces counteract the gravitational force in order to levitate the substrate carrier 150. The substrate carrier controller 155 may be configured to individually control the two active magnetic elements 113′ to maintain the substrate carrier in a levitating state.

Further, one or more further active magnetic elements 114 can be controlled by the substrate carrier controller 155. The further active magnetic elements 114′ interact with the second passive magnetic element 152. For example, the second passive magnetic element 152 may include a set of alternating permanent magnets, to generate a driving force as exemplarily indicated by the horizontal arrow in FIG. 5A. For instance, the number of further active magnetic elements 114′, which are simultaneously controlled to provide the driving force, can be 1 to 3 or more. Accordingly, at a first position, the substrate carrier is positioned below a first group of active magnetic elements and at a further, different position, the substrate is positioned below a further, different group of active magnetic elements. Typically, the substrate carrier controller 155 is configured to control which active magnetic elements provides a levitation force for a respective position. For example, the levitating force can be provided by subsequent active magnetic elements while the substrate is moving. Accordingly, the substrate carrier may be handed over from one set of active magnetic elements to another set of active magnetic elements.

In the second position, as exemplarily shown in FIG. 5B, two active magnetic elements 113′ provide a first magnetic force indicated by the left vertical arrow and a second magnetic force indicated by right vertical arrow. The substrate carrier controller 155 may be configured to control the two active magnetic elements 113′ to provide for an alignment in a vertical direction, for example the y-direction indicated in FIG. 5B. Additionally or alternatively, the substrate carrier controller 155 may be configured to control the two active magnetic elements 113′ to provide for an alignment, wherein the carrier assembly can be rotated in the x-y-plane. Both alignment movements can exemplarily be seen in FIG. 5B by comparing the position of the dotted substrate carrier and the position of the substrate carrier drawn with solid lines.

Accordingly, it is to be understood that the substrate carrier controller 155 may be configured for controlling the active magnetic elements 113′ for translationally aligning the substrate carrier in a vertical direction, e.g. with a mask carrier as described herein. Further, by controlling the active magnetic elements, the substrate carrier 150 may be positioned into a target vertical position. The substrate carrier 150 may be maintained in the target vertical position under the control of the substrate carrier controller 155. Further, the substrate carrier controller 155 can be configured for controlling the active magnetic elements 113′ for angularly aligning the substrate carrier 150 with respect to a first rotation axis, e.g. a rotational axis perpendicular to the substrate surface, e.g. a rotational axis extending in a z-direction as exemplarily indicated in FIG. 5B.

According to embodiments, which can be combined with other embodiments described herein, the positioning arrangement can be configured for providing an alignment, particularly a contactless alignment, of the substrate carrier with respect to the mask carrier, e.g. in a vertical direction, with an alignment range from 0.1 mm to 3 mm. Further, an alignment precision, particularly a contactless alignment precision, in the vertical direction can be 50 μm or below, for example 1 μm to 10 μm, such as 5 μm. Further, a rotational alignment precision, particularly a contactless rotational alignment precision, of the positioning arrangement can be 3° or below.

As described above, the one or more further active magnetic elements 114′ of the first drive structure 112 can be configured for providing a driving force along the extension of the first track, e.g. the x-direction. Accordingly, it is to be understood that the substrate carrier controller 155 can be configured to control the one or more further active magnetic elements 114′ to provide for an alignment in a transport direction, for example the x-direction in FIGS. 5A and 5B. Accordingly, an alignment of the substrate carrier in a transport direction (e.g. x-direction) can be provided with an alignment range extending along the length of the first track. In particular, an alignment precision, particularly a contactless alignment precision, in the transport direction can be 50 μm or below, for example 5 μm or 30 μm.

Accordingly, embodiments of the positioning arrangement as described herein provide for levitated substrate carrier movement which allows for a high precision in substrate positioning in a transport direction and/or a vertical direction. Further, embodiments of the positioning arrangement as described herein provide for improved alignment of a substrate carrier relative to a mask carrier, e.g. by horizontal and/or vertical and/or rotational alignment.

FIG. 6 shows a schematic side view of a positioning arrangement having a first guiding structure 111 being a first magnetic guiding structure and a first drive structure 112 being a first magnetic drive structure, as exemplarily described with reference to FIGS. 5A and 5B. Further, FIG. 6 shows that the positioning arrangement may have a second guiding structure 121 being a second magnetic guiding structure as well as a second drive structure 122 being a second magnetic drive structure. Accordingly, with exemplary reference to FIG. 6, it is to be understood that the optional features of the first track 110 as described with reference to FIGS. 5A and 5B, mutatis mutandis, may also be applied to the second track 120 of the positioning arrangement as described herein. In particular, the mask carrier 160 may include a first passive magnetic element 151 and a second passive magnetic element 152 as described with reference to FIGS. 5A and 5B. Further, the second guiding structure 121 may include a plurality of active magnetic elements 113 and the second drive structure 122 may include a plurality of further active magnetic elements 114, as described with reference to FIGS. 5A and 5B. Accordingly, similarly to the substrate carrier controller 155 for controlling levitation and transportation of the substrate carrier, a mask carrier controller can be provided for controlling levitation and transportation of the mask carrier. In particular, the principle of controlling levitation and transportation of the mask carrier, mutatis mutandis, corresponds to the principle of controlling levitation and transportation of the substrate carrier as described with reference to FIGS. 5A and 5B

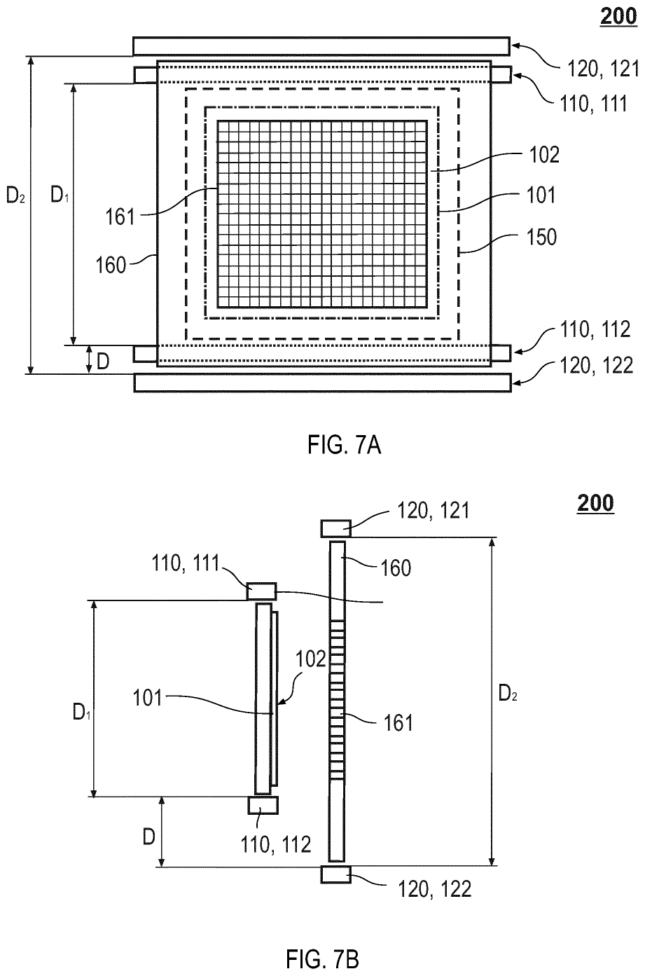

With exemplary reference to FIGS. 7A and 7B, a transportation system 200 for transporting a substrate carrier 150 and a mask carrier 160 in a processing system is described. According to embodiments which can be combined with any other embodiment described herein, the transportation system includes a first track 110 extending in a first direction. For example, in FIG. 7A the first direction corresponds to the x-direction. Further, according to embodiments described herein, the first track 110 is configured for contactless transportation of the substrate carrier 150. Typically, the substrate carrier 150 is configured for holding a substrate 101 having a substrate surface 102. Further, the transportation system 200 includes a second track 120 extending in the first direction, e.g. the x-direction as shown in FIG. 7A. Typically, the second track 120 is configured for contactless transportation of the mask carrier 160. As exemplarily shown in FIGS. 7A and 7B, the first track 110 and the second track 120 are offset by an offset distance D in a plane coplanar with the substrate surface.

Further, it is to be understood that the features with respect to the configuration of the first track 110 and the second track 120 of the positioning arrangement as described herein, e.g. with reference to FIGS. 5A, 5B and 6, may also be applied to the first track 110 and the second track 120 of the transportation system 200 as exemplarily shown in FIGS. 7A and 7B.

Accordingly, beneficially an improved transportation system for transporting a substrate carrier and a mask carrier is provided. In particular, by providing a transportation system which is configured for contactless transportation of a substrate carrier and the mask carrier, beneficially a generation of particles, e.g. generated due to a mechanical contact between the carriers and the transportation tracks, can be avoided during transportation of the carriers. Accordingly, embodiments described herein provide for an improved purity and uniformity of the layers deposited on the substrate, in particular since a particle generation is minimized when using the contactless transportation. Further, by providing a transportation system wherein a first track for a substrate carrier and a second track for a mask carrier are configured to correspond to a first track and the second track of the positioning arrangement as described herein, the transportation system can be used in combination with positioning arrangement, particularly without any intermediate adaption arrangement.

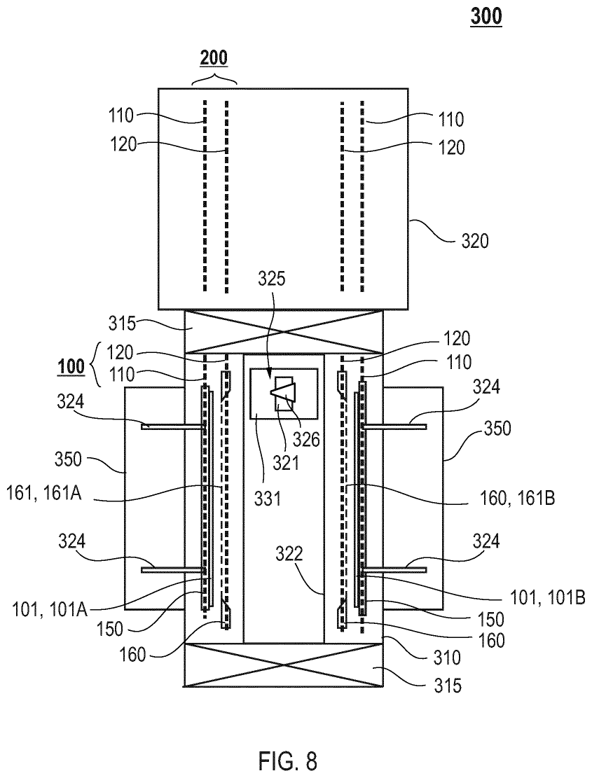

According to embodiments which can be combined with any other embodiments described herein, the first track 110 of the transportation system 200 includes a first guiding structure 111 and a first drive structure 112 which are spaced apart by a first distance D1, as exemplarily shown in FIGS. 8A and 8B. Further, the second track 120 of the transportation system 200 may include a second guiding structure 121 and a second drive structure 122 which are spaced apart by a second distance D2. Typically, the first distance D1 is smaller than the second distance D2.

According to embodiments which can be combined with any other embodiments described herein, the first guiding structure 111 of the first track 110 of the transportation system 200 can be a first magnetic guiding structure which may be configured as the first magnetic guiding structure of the positioning arrangement 100, as exemplarily described with reference to FIGS. 5A and 5B. Further, the first drive structure 112 of the first track 110 of the transportation system 200 can be a first magnetic drive structure which may be configured as the first magnetic drive structure of the positioning arrangement 100, as exemplarily described with reference to FIGS. 5A and 5B.

Accordingly, it is to be understood that the second guiding structure 121 of the transportation system 200 can be a second magnetic guiding structure which may be configured as the second magnetic guiding structure of the positioning arrangement 100, as exemplarily described with reference to FIGS. 5A, 5B and 6. Similarly, the second drive structure 122 of the transportation system 200 can be a second magnetic drive structure which may be configured as the second magnetic drive structure of the positioning arrangement 100, as exemplarily described with reference to FIGS. 5A, 5B and 6.

With exemplary reference to FIG. 8, a vacuum processing system according to another aspect of the present disclosure is described. In particular, according to embodiments which can be combined with any other embodiments described herein, the vacuum processing system 300 includes a vacuum processing chamber 310 having a positioning arrangement 100 according to any embodiments described herein. Further, the vacuum processing system 300 includes at least one further chamber 320 having a transportation system 200 according to any embodiments described herein. In particular, the vacuum processing chamber 310 can be configured for depositing organic material. Typically, a deposition source 325, particularly an evaporation source, is provided in a vacuum processing chamber 310. In particular, the deposition source 325 can be provided on a track or linear guide 322, as exemplarily shown in FIG. 8. The linear guide 322 may be configured for the translational movement of the deposition source 325. Further, a drive for providing a translational movement of deposition source 325 can be provided. In particular, a transportation apparatus for contactless transportation of the deposition source may be provided. As exemplarily shown in FIG. 8, the vacuum processing chamber 310 may have gate valves 315 via which the vacuum process chamber can be connected to an adjacent further chamber 320, e.g. a routing module or an adjacent service module. In particular, the gate valves allow for a vacuum seal to the adjacent further chamber and can be opened and closed for moving a substrate and/or a mask into or out of the vacuum processing chamber 310.

In the present disclosure, a “vacuum processing chamber”is to be understood as a vacuum chamber or a vacuum deposition chamber. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10−4 mbar to about 10⁻⁷ mbar, especially in the case that a second component besides the evaporated material is present in the vacuum chamber (such as a gas or the like).

With exemplary reference to FIG. 8, according to embodiments which can be combined with any other embodiment described herein, two substrates, e.g. a first substrate 101A and a second substrate 101B, can be supported on respective transportation tracks, particularly a first track 110 as described herein. Further, two tracks, e.g. two second tracks 120 as described herein, for providing mask carriers thereon can be provided. In particular, the tracks for transportation of a substrate carrier and/or a mask carrier may be configured as described with reference to FIGS. 1 to 6.

Typically, coating of the substrates may include masking the substrates by respective masks, e.g. by an edge exclusion mask or by a shadow mask. According to typical embodiments, the masks, e.g. a first mask 161A corresponding to a first substrate 101A and a second mask 161B corresponding to a second substrate 101B, are provided in a mask carrier 116 to hold the mask in a predetermined position, as exemplarily shown in FIG. 8.

According to some embodiments, which can be combined with other embodiments described herein, the substrate 101 is typically supported by a substrate carrier 150, which can be connected to an alignment system 350, e.g. by connecting elements 324. The alignment system 350 can be configured for adjusting the position of the substrate 101 with respect to the mask 161. Accordingly, it is to be understood that the substrate can be moved relative to the mask in order to provide for a proper alignment between the substrate and the mask during deposition of the organic material. According to a further embodiment, which can be combined with other embodiments described herein, alternatively or additionally the mask carrier holding the mask can be connected to the alignment system 350. Accordingly, either the mask can be positioned relative to the substrate 101 or the mask 330 and the substrate 101 can both be positioned relative to each other. Accordingly, an alignment system as described herein allows for a proper alignment of the masking during the deposition process, which is beneficial for high quality or OLED display manufacturing.

Examples of an alignment of a mask and a substrate relative to each other include alignment units, which allow for a relative alignment in at least two directions defining a plane, which is essentially parallel to the plane of the substrate and the plane of the mask. For example, an alignment can at least be conducted in an x-direction and a y-direction, i.e. two Cartesian directions defining the above-described parallel plane. Typically, the mask and the substrate can be essentially parallel to each other. Specifically, the alignment can further be conducted in a direction essentially perpendicular to the plane of the substrate and the plane of the mask. Thus, an alignment unit is configured at least for an X-Y-alignment, and specifically for an X-Y-Z-alignment of the mask and the substrate relative to each other. One specific example, which can be combined with other embodiments described herein, is to align the substrate in x-direction, y-direction and z-direction to a mask, which can be held stationary in the vacuum processing chamber.

With exemplary reference to FIG. 8, a source support 331 configured for the translational movement of the deposition source 325 along the linear guide 322 may be provided. Typically, the source support 331 supports an evaporation crucible 321 and a distribution assembly 326 provided over the evaporation crucible. Accordingly, the vapor generated in the evaporation crucible can move upwardly and out of the one or more outlets of the distribution assembly. Accordingly, the distribution assembly 326 is configured for providing evaporated organic material, particularly a plume of evaporated source material, from the distribution assembly to the substrate 101.

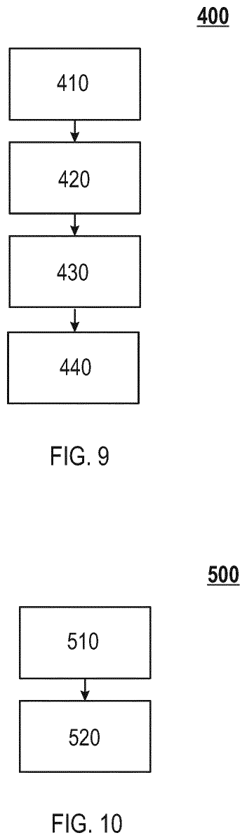

With exemplary reference to the flow chart shown in FIG. 9, embodiments of a method 400 for positioning a substrate carrier 150 relative to a mask carrier 160 are described. According to embodiments which can be combined with any other embodiments described herein, the method 400 includes positioning (block 410) the substrate carrier in a first position by using a first track configured for contactless transportation of the substrate carrier. Further, the method 400 includes positioning (block 420) the mask carrier in a second position by using a second track configured for contactless transportation of the mask carrier. Additionally, the method 400 includes holding (block 430) the mask carrier by using an holding arrangement arranged between the first transportation track and the second transportation track and aligning (block 440) the substrate carrier relative to the mask carrier. In particular, embodiments of the method 400 for positioning a substrate carrier 150 relative to a mask carrier 160 may include using a positioning arrangement 100 as described herein. Accordingly, an improved method for positioning a substrate carrier relative to a mask carrier is provided.

With exemplary reference to the flow chart shown in FIG. 10, embodiments of a method 500 for transporting a substrate carrier 150 and a mask carrier 160 through a processing system are described. According to embodiments which can be combined with any other embodiments described herein, the method 500 includes transporting (block 510) the substrate carrier on a first track 110 configured for contactless transportation of the substrate carrier 150. Typically, the substrate carrier 150 is configured for holding a substrate having a substrate surface. Further, the method 500 includes transporting (block 520) the mask carrier 160 on a second track 120 configured for contactless transportation of the mask carrier 160, wherein the first track 110 and the second track 120 are offset by an offset distance D in a plane coplanar with the substrate surface.

In particular, embodiments of the method 400 for transporting a substrate carrier 150 and a mask carrier 160 through a processing system may include using a transportation system 200 as described herein. Accordingly, an improved method for transporting a substrate carrier 150 and a mask carrier 160 through a processing system, e.g. a vacuum processing system 300 as described herein, is provided.

While the foregoing is directed to embodiments of the disclosure, other and further embodiments of the disclosure may be devised without departing from the basic scope thereof, and the scope thereof is determined by the claims that follow.

In particular, this written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. A positioning arrangement for positioning a substrate carrier and a mask carrier in a vacuum chamber, comprising:
a first track extending in a first direction and configured for transportation of the substrate carrier configured for holding a substrate having a substrate surface;
a second track extending in the first direction and configured for transportation of the mask carrier, wherein the first track and the second track are offset by an offset distance in a plane coplanar with the substrate surface; and
a holding arrangement configured for holding the mask carrier, wherein the holding arrangement is arranged between the first track and the second track.

2. The positioning arrangement according to claim 1, wherein the first track is configured for contactless transportation of the substrate carrier, and wherein the second track is configured for contactless transportation of the mask carrier.

3. The positioning arrangement according to claim 2, wherein the holding arrangement comprises at least one holding element configured to be movable in a moving direction being different to a substrate transport direction.

4. The positioning arrangement according to claim 1, further comprising an alignment system configured for aligning the substrate carrier relative to the mask carrier.

5. The positioning arrangement according to claim 1, wherein the first track comprises a first guiding structure and a first drive structure which are spaced apart by a first distance.

6. The positioning arrangement according to claim 1, wherein the second track comprises a second guiding structure and a second drive structure which are spaced apart by a second distance.

7. The positioning arrangement according to according to claim 1, wherein the first track comprises a first guiding structure and a first drive structure which are spaced apart by a first distance, wherein the second track comprises a second guiding structure and a second drive structure which are spaced apart by a second distance, and wherein the first distance is smaller than the second distance.

8. The positioning arrangement according to claim 5, wherein the first guiding structure is a first magnetic guiding structure and the first drive structure is a first magnetic drive structure, and/or wherein the second guiding structure is a second magnetic guiding structure and the second drive structure is a second magnetic drive structure.

9. A transportation system for transporting a substrate
carrier and a mask carrier in a processing system, comprising:
a first track extending in a first direction and for contactless transportation of the substrate carrier configured for holding a substrate having a substrate surface; and
a second track extending in the first direction and configured for contactless transportation of the mask carrier, wherein the first track and the second track are offset by an offset distance in a plane coplanar with the substrate surface.

10. The transportation system according claim 9, wherein the first track comprises a first guiding structure and a first drive structure which are spaced apart by a first distance.

11. The transportation system according to claim 9, wherein the second track comprises a second guiding structure and a second drive structure which are spaced apart by a second distance.

12. The transportation system according to claim 10, wherein the first distance is smaller than the second distance.

13. A vacuum processing system comprising:
a vacuum processing chamber having a positioning arrangement for positioning a substrate carrier and a mask carrier in a vacuum chamber, the positioning arrangement comprising:
a first track extending in a first direction and configured for transportation of the substrate carrier configured for holding a substrate having a substrate surface;
a second track extending in the first direction and configured for transportation of the mask carrier, wherein the first track and the second track are offset by an offset distance in a plane coplanar with the substrate surface, and a holding arrangement configured for holding the mask carrier, wherein the holding arrangement is arranged between the first track and the second track; and
at least one further chamber having a transportation system for transporting a substrate carrier and a mask carrier in a processing system, the transportation system comprising:
a first track extending in a first direction and for contactless transportation of the substrate carrier configured for holding a substrate having a substrate surface; and
a second track extending in the first direction and configured for contactless transportation of the mask carrier, wherein the first track and the second track are offset by an offset distance in a plane coplanar with the substrate surface.

14. A method for positioning a substrate carrier relative to a mask carrier, comprising:
positioning the substrate carrier in a first position by using a first track configured for contactless transportation of the substrate carrier;
positioning the mask carrier in a second position by using a second track configured for contactless transportation of the mask carrier;
holding the mask carrier by using an holding arrangement arranged between the first track and the second track; and
aligning the substrate carrier relative to the mask carrier.

15. A method for transporting a substrate carrier and a mask carrier through a processing system, comprising:
transporting the substrate carrier on a first track configured for contactless transportation of the substrate carrier configured for holding a substrate having a substrate surface; and
transporting the mask carrier on a second track configured for contactless transportation of the mask carrier, wherein the first track and the second track are offset by an offset distance in a plane coplanar with the substrate surface.

16. The positioning arrangement according to claim 4, wherein the first track comprises a first guiding structure and a first drive structure which are spaced apart by a first distance.

17. The positioning arrangement according to claim 4, wherein the second track comprises a second guiding structure and a second drive structure which are spaced apart by a second distance.

18. The positioning arrangement according to claim 5, wherein the second track comprises a second guiding structure and a second drive structure which are spaced apart by a second distance.

19. The positioning arrangement according to claim 6, wherein the first guiding structure is a first magnetic guiding structure and the first drive structure is a first magnetic drive structure, and/or wherein the second guiding structure is a second magnetic guiding structure and the second drive structure is a second magnetic drive structure.

20. The positioning arrangement according to claim 7, wherein the first guiding structure is a first magnetic guiding structure and the first drive structure is a first magnetic drive structure, and/or wherein the second guiding structure is a second magnetic guiding structure and the second drive structure is a second magnetic drive structure.
